(19) United States
(12) Patent Application Publication
(10) Pub. No.: US 2020/0106473 A1
(43) Pub. Date: Apr. 2, 2020

(54) WIRELESS COMMUNICATION DEVICE

(71) Applicant: QUALCOMM Incorporated, San Diego, CA (US)

(72) Inventors: Sujiang RONG, San Diego, CA (US); Li LIU, San Diego, CA (US); Gurkanwal SAHOTA, San Diego, CA (US); Kevin Hsi Huai WANG, San Diego, CA (US)

(21) Appl. No.: 16/145,588

(22) Filed: Sep. 28, 2018

(51) Int. Cl. H04B 1/50; H03H 7/21; H04L 25/02

(52) U.S. Cl. CPC H04B 1/50; H04L 25/02; H03H 7/21

(57) ABSTRACT

A wireless communication device includes: a housing configured to retain components of the wireless communication device; an antenna unit configured to receive first free-space millimeter-wave signals and convert these signals to first electronic millimeter-wave signals; a processor disposed in the housing; and front-end circuitry communicatively coupled to the antenna unit, the front-end circuitry coupled to the processor by at least one transmission line; where the front-end circuitry is configured to: receive the first electronic millimeter-wave signals from the antenna unit; convert the first electronic millimeter-wave signals to first reduced-frequency signals each having a lower frequency than the first electronic millimeter-wave signals; and convey the first reduced-frequency signals over a same transmission line of the at least one transmission line in a multiplexed manner with different ones of the first reduced-frequency signals having different conveyance characteristics such that the different ones of the first reduced-frequency signals can be separately processed.

### BACKGROUND

Wireless communication devices are increasingly popular and increasingly complex, and continuing to evolve. For example, mobile telecommunication devices have progressed from simple phones, to smart phones with multiple communication capabilities (e.g., multiple cellular communication protocols, Wi-Fi, BLUETOOTH® and other short-range communication protocols), supercomputing processors, cameras, etc. The protocols and frequencies of communications used by mobile telecommunication devices have also changed. Higher frequencies are now used than before to provide more and/or different capabilities. To support the use of these frequencies for wireless communication, a telecommunication device typically has one or more antennas disposed near one or more edges of the telecommunication device. The antenna is connected to a processor, typically disposed near a middle of the telecommunication device, to receive signals from the processor and to convey the signals to other devices, and to receive signals from other devices and to convey these signals to the processor. Further, different polarization signals may be received, converted to electronic signals, and the electronic signals sent to the processor via separate transmission lines.

### SUMMARY

An example of a wireless communication device includes: a housing configured to retain components of the wireless communication device; an antenna unit configured to receive first free-space millimeter-wave signals and convert the first free-space millimeter-wave signals to first electronic millimeter-wave signals; a processor disposed in the housing; and front-end circuitry communicatively coupled to the antenna unit, the front-end circuitry coupled to the processor by at least one transmission line; where the front-end circuitry is configured to: receive the first electronic millimeter-wave signals from the antenna unit; convert the first electronic millimeter-wave signals to first reduced-frequency signals each having a lower frequency than the first electronic millimeter-wave signals; and convey the first reduced-frequency signals over a same transmission line of the at least one transmission line in a multiplexed manner with different ones of the first reduced-frequency signals having different conveyance characteristics such that the different ones of the first reduced-frequency signals can be separately processed.

Another example of wireless communication device includes: retaining means for retaining components of the wireless communication device; processing means; receiving means for receiving first free-space millimeter-wave signals and converting the first free-space millimeter-wave signals to first electronic millimeter-wave signals; and converting means, coupled to the receiving means, for converting the first electronic millimeter-wave signals to first reduced-frequency signals each having a lower frequency than the first electronic millimeter-wave signals, and for providing the first reduced-frequency signals in a multiplexed manner over a same first transmission line to the processing means with different ones of the first reduced-frequency signals having different conveyance characteristics such that the different ones of the first reduced-frequency signals can be separately processed.

An example of a method of providing information from free-space millimeter-wave signals to a processor of a wireless communication device includes: receiving free-space millimeter-wave signals and converting the free-space millimeter-wave signals to a plurality of electronic millimeter-wave signals; converting a plurality of the electronic millimeter-wave signals to a plurality of reduced-frequency signals each having a lower frequency than the plurality of electronic millimeter-wave signals; and providing the plurality of reduced-frequency signals in a multiplexed manner over a same transmission line for conveyance to the processor with different ones of the plurality of reduced-frequency signals having different conveyance characteristics such that the different ones of the plurality of reduced-frequency signals can be separately processed.

Another example of a wireless communication device includes: an antenna unit configured to receive multiple free-space composite signals having different inbound millimeter-wave carrier frequencies and each comprising multiple free-space component signals of different polarizations, the antenna unit configured to convert the multiple free-space component signals into electronic component signals; radio-frequency circuitry, coupled to the antenna unit, configured to convert the electronic component signals to intermediate signals each having a lower frequency than the inbound millimeter-wave carrier frequencies and to convey the intermediate signals over multiple coaxial lines such that each coaxial line concurrently conveys multiple intermediate signals of different intermediate carrier frequencies; and intermediate-frequency circuitry, coupled to the radio-frequency circuitry, configured to convert each of the intermediate signals to a respective baseband signal and to provide each respective baseband signal to a processor of the wireless communication device.

### BRIEF DESCRIPTION OF THE DRAWINGS

FIG. 1 is a schematic diagram of a communication system.

FIG. 2 is a block diagram of components of a wireless communication device shown in FIG. 1.

FIG. 3 is a block diagram of components of an example of a transceiver shown in FIG. 2.

FIG. 4 is a block diagram of components of another example of a transceiver shown in FIG. 2.

FIG. 5 is a block diagram of components of another example of a transceiver shown in FIG. 2.

FIG. 6 is a block diagram of components of another example of a transceiver shown in FIG. 2.

FIGS. 7-9 are further examples of systems according to the disclosure.

FIG. 10 is a block flow diagram of a method of using free-space millimeter-wave signals at a wireless communication device.

### DETAILED DESCRIPTION

Techniques are discussed herein for coupling millimeter-wave antennas and processors of mobile wireless communication devices. For example, a processor in a mobile wireless communication device may be disposed centrally in the device, e.g., to facilitate quick processing of data for various components of the device. One or more antennas may be disposed near a perimeter of the device, e.g., to help improve reception and/or transmission of wireless signals. At millimeter-wave frequencies, losses may be too high for transmission of signals between the antenna(s) and the processor. Signals may be transferred between the processor and the antenna(s) at one or more intermediate frequencies over one or more transmission lines. The number of transmission lines used may be reduced by multiplexing signals and conveying multiple multiplexed signals over a single transmission line. For example, signals may be frequency division multiplexed and/or time division multiplexed. Multiple transmission lines may be provided, and multiple multiplexed signals may be conveyed over each of the multiple transmission lines. These techniques are not exhaustive, and other techniques may be used.

Items and/or techniques described herein may provide one or more of the following capabilities, as well as other capabilities not mentioned. Multiple signals may be transferred between a processor and one or more antennas of a mobile wireless communication device over a single transmission line. The signals may be frequency division multiplexed and transferred over the transmission line concurrently. The signals may be time division multiplexed and transferred over the transmission line at different times. A quantity of transmission lines disposed between a processor and one or more antennas of a mobile wireless communication device may be reduced or even minimized. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

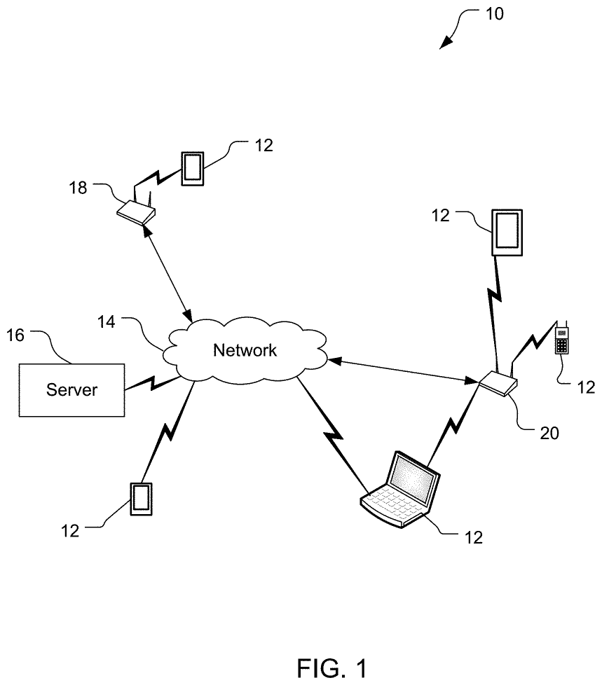

Referring to FIG. 1, a communication system 10 includes wireless communication devices 12, a network 14, a server 16, and access points (APs) 18, 20. The system 10 is a communication system in that components of the system 10 can communicate with one another directly or indirectly, e.g., via the network 14 and/or one or more of the access points 18, 20 (and/or one or more other devices not shown, such as one or more base transceiver stations). For indirect communications, the communications may be altered during transmission from one entity to another, e.g., to alter header information of data packets, to change format, etc. The example wireless communication devices 12 shown include mobile phones (including smartphones), a laptop computer, and a tablet computer. Still other mobile devices may be used, whether currently existing or developed in the future.

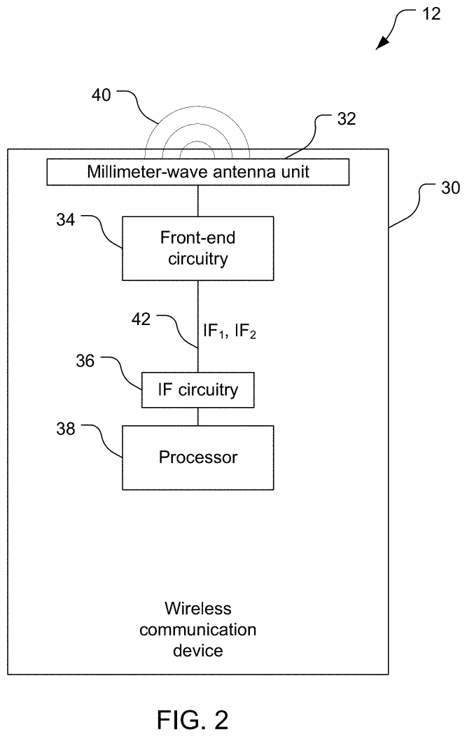

Referring also to FIG. 2, an example of any of the wireless communication devices 12 includes a housing 30, an antenna unit 32, front-end circuitry 34, intermediate-frequency (IF) circuitry 36, and a processor 38. One or both of the front-end circuitry 34 and/or the IF circuitry 36 may be implemented as chips, although non-chip configurations may be used. The housing 30 is configured to retain, e.g., hold and/or contain, components of the wireless communication device 12. The antenna unit 32, the front-end circuitry 34, the IF circuitry 36, and the connections between them, form a transceiver configured to convey signals, e.g., millimeter-wave wireless signals, corresponding to baseband signals from the processor 38 and to receive signals, e.g., millimeter-wave wireless signals, and provide corresponding baseband signals to the processor 38. The antenna unit 32 is disposed proximate to (at or adjacent to) at least one edge of the housing 30 and the front-end circuitry 34 is disposed proximate to the antenna unit 32. The antenna unit 32 includes one or more millimeter-wave radiating elements each configured to transmit and receive free-space millimeter-wave wireless signals 40. That is, each radiating element is configured to receive free-space millimeter-wave signals and to convert (here, transduce) the free-space signals into electronic signals that are also millimeter-wave signals. The antenna unit 32 is configured to provide the electronic signals to the front-end circuitry 34. Further, the antenna unit 32 is configured to receive millimeter-wave electronic signals from the front-end circuitry 34, to convert the electronic signals to free-space millimeter-wave signals, and to transmit the free-space millimeter-wave wireless signals 40, e.g., into the air. The signals 40 may be composite signals, e.g., with each of the signals composed of component signals such as a vertically-polarized signal and a horizontally-polarized signal. The signals 40 may include multiple composite signals, e.g., with different composite signals having different carrier frequencies. The front-end circuitry 34 is communicatively coupled to the antenna unit 32 by one or more transmission lines. The front-end circuitry 34, which may be referred to as radio frequency (RF) circuitry, is configured to receive the electronic signals from the antenna unit 32 and to convert the electronic signals to reduced-frequency signals (e.g., intermediate-frequency signals). The front-end circuitry 34 is communicatively coupled to the IF circuitry 36 by one or more transmission lines 42, e.g., one or more coaxial cables. The front-end circuitry 34 and the IF circuitry 36 are configured to convey signals between them in a multiplexed manner over the one or more transmission lines 42. The front-end circuitry 34 is configured to convey multiple ones of the reduced-frequency signals, here IF signals, over a single one of one or more transmission lines 42 in a multiplexed manner to the IF circuitry 36. For example, the front-end circuitry 34 may convey multiple IF signals concurrently using frequency division multiplexing to the IF circuitry 36 over any one of the one or more transmission lines 42. The front-end circuitry 34 may convey multiple IF signals over each of the transmission lines 42 if there is more than one transmission line 42. The IF circuitry 36 is configured to convert IF signals from the transmission line(s) 42 to baseband signals and provide the baseband signals to the processor 38. Similarly, the IF circuitry 36 is configured to convert baseband signals from the processor 38 to IF signals and to provide the IF signals to the front-end circuitry 34 via the transmission line(s) 42. The IF circuitry 36 is disposed proximate to the processor 38, which is displaced from the antenna unit 32 such that the processor 38 is remote from the antenna unit 32. The processor 38 may be disposed centrally in the housing 30, as in the example shown in FIG. 2, e.g., to reduce lengths of connections between the processor 38 and other components of the wireless communication device 12. The processor 38 may be displaced far enough from the antenna unit 32 that transmission losses would be unacceptably high to convey the signals from the antenna unit 32 to the processor 38 without converting the signals to a lower frequency (or frequencies).

The processor 38, the IF circuitry 36, and the front-end circuitry 34 may provide multiple signal chains that may be used, for example, to communicate in different networks and/or for different purposes (e.g., Wi-Fi communication, multiple frequencies of Wi-Fi communication, satellite positioning, one or more types of cellular communications (e.g., GSM (Global System for Mobiles), CDMA (Code Division Multiple Access), LTE (Long-Term Evolution), 5G, etc.). The processor 38 may be configured to send communication signals to, and to receive communication signals from, the IF circuitry 36 and the front-end circuitry 34. The processor 38 is configured to produce and send baseband signals to the IF circuitry 36 to induce transmission of the millimeter-wave wireless signals 40, e.g., to relay voice information from the user to another device, etc. The processor 38 may be configured to produce an outbound communication signal, for example in a baseband, and to send this signal to the IF circuitry 36. The communication signal provides appropriate information, e.g., outgoing voice, data for upload, etc. for transmission by the antenna unit 32, e.g., to a cellular tower, an access point. The processor 38 is further configured to process baseband signals from the IF circuitry 36 to interpret information in the IF signals and to take appropriate action (e.g., cause a display to show information to a user, cause a speaker to play sound, etc.). The processor 38 may be configured to receive an inbound communication signal received via the antenna unit 32. The processor 38 may include memory that stores instructions that may be executed by the processor 38, e.g., the memory being a non-transitory processor-readable medium storing software instructions that are executable by the processor 38.

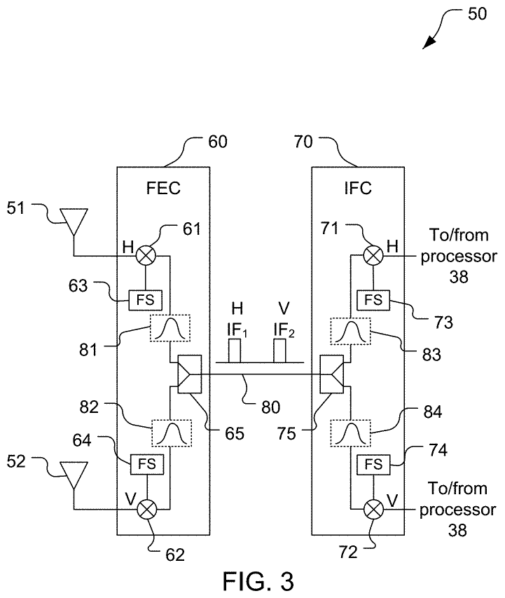

Referring also to FIG. 3, an example transceiver 50, i.e., an example of the antenna unit 32, the front-end circuitry 34, the transmission line(s) 42, and the intermediate-frequency circuitry 36, includes radiating elements 51, 52, front-end circuitry (FEC) 60, intermediate-frequency circuitry (IFC) 70, and a transmission line 80. While shown separately in FIG. 3, the radiating elements 51, 52 may be a single physical radiator, here capable of dual-polarization radiation and reception. Further, the radiating elements 51, 52 and the FEC 60 may be implemented in a single module, e.g., a chip or other single physical unit. The radiating elements 51, 52 may be parts of a larger antenna set, e.g., a phased-array of radiating elements. The transceiver 50 is configured to convert baseband signals from the processor 38 to IF signals, convey the IF signals in a multiplexed manner over the transmission line 80 to the FEC 60, convert the IF signals to millimeter-wave wireless signals, and to transmit the millimeter wave wireless signals into the air with different polarities. In this example, the baseband signals correspond to different polarities of free-space signals, here labeled H and V for horizontal and vertical polarization. Signals in FIG. 3 (and other figures) are labeled H and V (or H1, H2, V1, or V2) to indicate that the respective signals correspond to horizontally-polarized or vertically-polarized free-space signals even though the labeled signal may not have a polarization. The transceiver 50 is also configured to receive millimeter-wave wireless signals of the different polarities, convert the received millimeter-wave wireless signals to IF signals, convey the IF signals in a multiplexed manner over the transmission line to the IF circuitry, convert the IF signals to baseband signals, and provide the baseband signals to the processor 38. Alternatively, as discussed further below, the FEC 60 could be configured to convert received signals directly to signals at baseband frequencies and provide these signals to the processor 38 and vice versa (i.e., receive baseband signals from the processor 38, convert these signals to millimeter-wave (mm-wave) frequency signals, and provide these signals to the antenna unit 32). The transceiver 50 is configured to frequency division multiplex the IF signals over the transmission line 80 concurrently. One or more other multiplexing techniques may, however, be used. For example, the IF signals could be time division multiplexed over the transmission line 80. As another example, the IF signals could be both frequency division multiplexed and time division multiplexed over the transmission line 80, having different carrier frequencies and being conveyed at different times (i.e., having different times of conveyance).

For signal reception, the transceiver 50 is configured to receive millimeter-wave wireless signals of different polarities and provide corresponding baseband signals to the processor 38. The radiating elements 51, 52 are configured to receive free-space millimeter-wave signals of respective polarizations, here horizontal and vertical polarizations, respectively. The radiating elements 51, 52 are configured to transduce the received signals into corresponding electronic signals and to provide the electronic signals to mixers 61, 62. The mixers 61, 62 are configured to downconvert the electronic signals to intermediate frequencies (i.e., to signals with intermediate carrier frequencies) using reference frequency signals from frequency synthesizers 63, 64, respectively. The frequency synthesizers 63, 64 include respective phase-locked loops (PLLs) for use in producing signals of different (intermediate) frequencies and vice versa, e.g., producing single-carrier-frequency signals from signals of different (intermediate) frequencies. The frequency synthesizers 63, 64 are shown as separate frequency synthesizers (with separate PLLs), but a single frequency synthesizer may be used. The intermediate frequencies are intermediate in that the intermediate frequencies are lower than the millimeter-wave frequencies of the received free-space signals and higher than a baseband frequency of signals provided to the processor 38. In this example, the frequency of the received horizontal polarization signal and the frequency of the received vertical polarization signal are the same. While the polarizations of the signals are lost when transduced by the radiating elements 51, 52, the corresponding signals are labeled and referred to as H and V for ease of understanding. The H and V electronic signals are converted to different intermediate frequencies IF₁, IF₂ by the mixers 61, 62 using the H and V signals from the radiating elements 51, 52 and signals from the frequency synthesizers 63, 64 as inputs, respectively. The IF frequencies may be any of a variety of frequencies, but typically are less than about half of the carrier frequency of signals received by the radiating elements 51, 52. For example, the radiating elements 51, 52 may receive signals with carrier frequencies in mm-wave bands such as the 26 GHz band, the 28 GHz band, the 39 GHz band, and/or the 43 GHz band, etc., and the intermediate frequencies may be less than half of each respective band. For example, IF₁ may be between 6.0 GHz and 7.1 GHz and IF₂ may be between 10.5 GHz and 11.6 GHz. The different intermediate frequencies may be separated enough, and such that neither is a harmonic of the other, to help avoid interference between the IF signals.

A combiner/splitter 65 of the FEC 60 is configured to receive the H and V IF signals and multiplex the IF signals onto the transmission line 80. Here, the combiner/splitter 65 is configured to combine the IF signals and convey the IF signals over the transmission line 80 concurrently. For example, the combiner/splitters 65, 75 may be power combiner/splitters such as Wilkinson combiners/splitters.

A combiner/splitter 75 of the IFC 70 is configured to receive the H and V IF signals from the transmission line 80 and de-multiplex the IF signals. Here, the combiner/splitter 75 is configured to separate the IF signals, to convey the H IF signal to a mixer 71, and to convey the V IF signal to a mixer 72.

The mixers 71, 72 are configured to downconvert the IF signals to baseband signals and to provide the baseband signals to the processor 38. The mixers 71, 72 use reference signals from frequency synthesizers 73, 74, respectively, to downconvert the IF signals to baseband signals at baseband frequency(ies). The frequency synthesizers 73, 74 include respective PLLs for use in receiving and producing signals with various carrier frequencies to support carrier aggregation. The frequency synthesizers 73, 74 are shown as separate frequency synthesizers (with separate PLLs), but a single frequency synthesizer may be used. The mixers 71, 72 and the frequency synthesizers 73, 74 are configured to convert the IF signals such that the H and V baseband signals have the same frequency. The mixers 71, 72 are communicatively coupled to the processor 38 such that the H and V baseband signals are provided to the processor 38.

For signal transmission, the transceiver 50 is configured to receive baseband signals from the processor 38 and to provide corresponding millimeter-wave signals to the radiating elements 51, 52 to radiate corresponding signals with different polarizations. The processor 38 is configured to provide H and V baseband signals to the mixers 71, 72, respectively. The mixers 71, 72 are configured to use the reference signals from the frequency synthesizers 73, 74, respectively to upconvert the H and V baseband signals to H and V IF signals at the IF frequencies IF₁, IF₂, respectively, and to provide the IF signals to the combiner/splitter 75. The combiner/splitter 75 is configured to combine the IF signals from the mixers 71, 72 and multiplex the IF signals over the transmission line 80 to the FEC 60. The combiner/splitter 65 of the FEC 60 is configured to separate the IF signals, to provide the H IF signal to the mixer 61, and to provide the V IF signal to the mixer 62. The mixers 61, 62 are configured to use the reference signals from the frequency synthesizers 63, 64, respectively to upconvert the H and V IF signals to H and V electronic signals at a millimeter-wave frequency, and to provide the electronic signals to the radiating elements 51, 52, respectively. The radiating elements 51, 52 are configured to radiate the respective H and V electronic signals as free-space millimeter-wave signals with respective, different, polarizations (here horizontal and vertical polarizations, respectively).

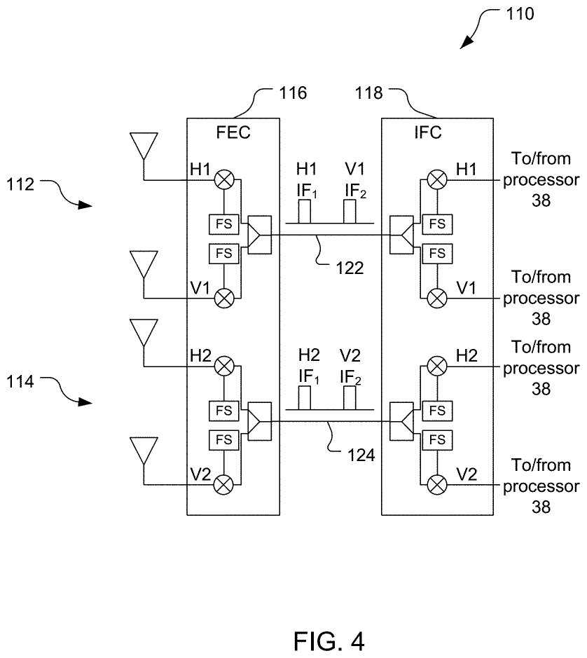

The FEC 60 and the IFC 70 optionally include bandpass filters 81, 82, 83, 84. The filters 81, 83 are configured to pass signals at the intermediate frequency IF₁ and the filters 82, 84 are configured to pass signals at the intermediate frequency IF₂. The filters 81-84 may help the integrity of the H and V signals and/or may help to isolate the intermediate-frequency signals while conveyed on the same transmission line, here the transmission line 80. Other transceivers, including the transceivers discussed below with respect to FIGS. 4-6, may also include appropriate bandpass filters although no such filters are shown in these figures to reduce congestion in the figures.

Referring to FIG. 4, an example transceiver 110, i.e., an example of the antenna unit 32, the front-end circuitry 34, the transmission line(s) 42, and the intermediate-frequency circuitry 36, includes two transceivers 112, 114. The transceiver 110 is configured to support carrier aggregation (CA), with the transceiver 112 configured to receive and transmit free-space millimeter-wave signals having a first carrier frequency and the transceiver 114 configured to receive and transmit free-space millimeter-wave signals having a second carrier frequency, different from the first carrier frequency. Each of the transceivers 112, 114 may be configured similarly to the transceiver 50 shown in FIG. 3 and discussed above, but configured to transmit and receive free-space millimeter-wave signals having respective carrier frequencies. The transceiver 112 is configured to receive a horizontally-polarized free-space millimeter-wave signal having the first carrier frequency and convert this signal to a corresponding electronic signal H1, and to receive a vertically-polarized free-space millimeter-wave signal having the first carrier frequency and convert this signal to a corresponding electronic signal V1. The transceiver 112 is configured to convert the electronic signals H1, V1 into corresponding intermediate-frequency signals having respective intermediate-frequency carrier frequencies IF₁, IF₂, and to convey the intermediate frequency signals over a single transmission line 122 in a multiplexed manner between an FEC 116 and an IFC 118 of the transceiver 112. The transceiver 112 is further configured to convert the intermediate-frequency signals to baseband signals and provide the baseband signals to the processor 38. The transceiver 114 is configured to receive a horizontally-polarized signal and a vertically-polarized signal having the second carrier frequency, to convert these signals into respective electronic signals H2, V2, and to process the signals similarly to the discussion above with respect to the transceiver 112. As shown in FIG. 4, the transceiver 114 may be configured to convey the signals H2, V2 in a multiplexed manner over a single transmission line 124 with the same intermediate-frequency carrier frequencies IF₁, IF₂ that the transceiver 112 uses to convey the signals H1, V1 over the transmission line 122. The transceiver 114 may, however, be configured to convey the signals H2, V2 over the transmission line 124 with one or more different intermediate-frequency carrier frequencies than the intermediate-frequency carrier frequencies IF₁, IF₂ used by the transceiver 112 to convey the signals H1, V1 over the transmission line 122. Indeed, as discussed further below, the H1, H2, V1, and V2 signals could all have different (intermediate or baseband) carrier frequencies and be conveyed over a single transmission line between a front-end circuit and an intermediate-frequency circuit or a processor. For example, if the transceiver 112 and the transceiver 114 are implemented on a single chip, the same PLL may be used to downconvert the H1 signal and the H2 signal, in which case the H1 intermediate frequency and the H2 intermediate frequency would be different. A single, but different, PLL could be used to downconvert the V1 and V2 signals, resulting in different frequencies for the intermediate V1 signal and the intermediate V2 signal. Thus, using a single chip for the transceivers, fewer PLLs (here, two instead of four) may be used than if the transceivers 112, 114 are implemented on separate chips.

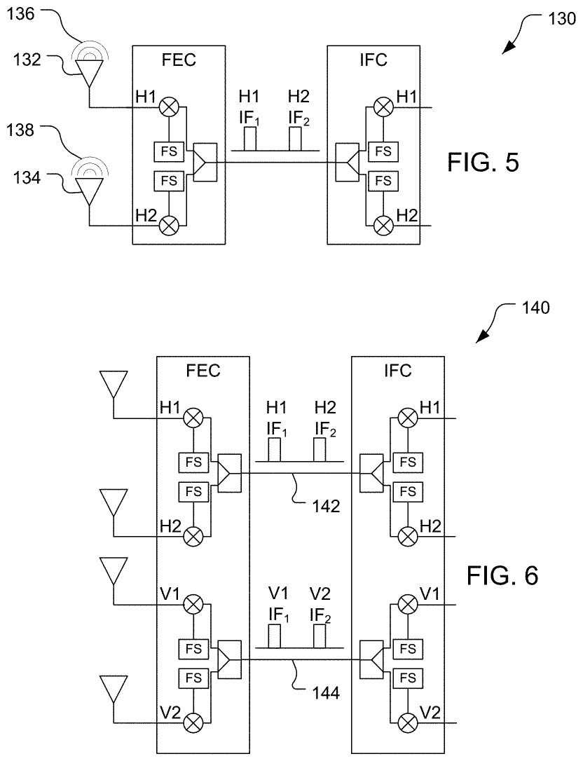

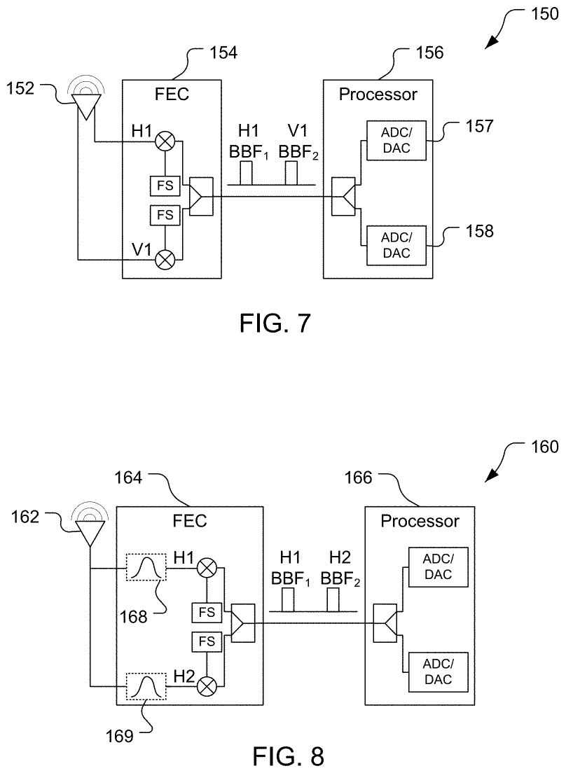

Still other transceiver configurations may be used. Referring to FIG. 5, another example transceiver 130 is configured similarly to the transceiver 50 shown in FIG. 3 except that the transceiver 130 is configured to receive and transmit horizontally-polarized free-space millimeter-wave signals having two different carrier frequencies instead of horizontally and vertically polarized signals having the same carrier frequency. Here, radiating elements 132, 134 are both configured to receive and transmit horizontally-polarized free-space signals 136, 138, respectively. Referring to FIG. 6, another example transceiver 140 is configured similarly to the transceiver 110 shown in FIG. 4 except that the transceiver 140 is configured to transfer intermediate-frequency signals corresponding to horizontally-polarized free-space millimeter-wave signals having different carrier frequencies over a single transmission line 142 and to transfer intermediate-frequency signals corresponding to vertically-polarized free-space millimeter-wave signals having the different carrier frequencies over a single transmission line 144. That is, the transceiver 140 is configured to convey intermediate signals that correspond to the same polarization of free-space signals having different carrier frequencies over a single transmission line, rather than intermediate signals that correspond to free-space signals having different polarizations and the same carrier frequency.

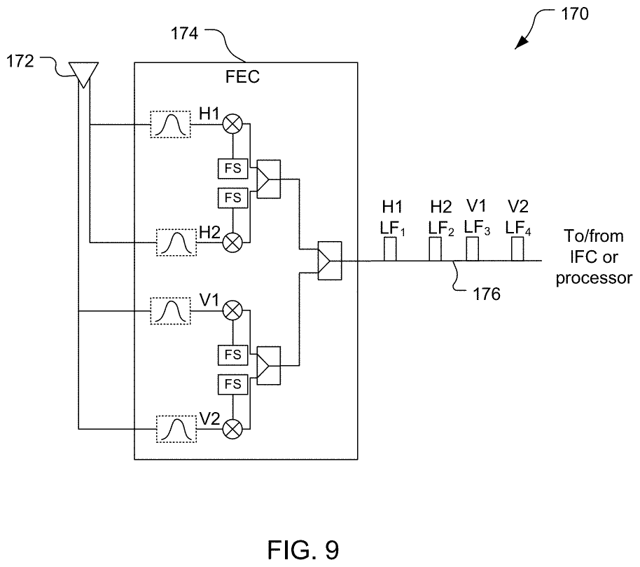

Still other configurations may be used. For example, referring to FIG. 7, a system 150 comprises a radiating element 152 and may convert signals between mm-wave frequencies and baseband frequencies, omitting an IFC. The radiating element 152 is configured as a dual-polarization antenna to receive and transmit mm-wave-frequency signals in horizontal and vertical polarizations. The signals of different polarizations may be fed to and drawn from the radiating element 152 at different locations (e.g., feed points) as shown. The FEC 154 may be configured similarly to the FEC 60 shown in FIG. 3, but the FEC 154 is configured to convert between signals at mm-wave frequencies and signals at baseband frequencies. The FEC 154 can downconvert received mm-wave-frequency signals of the two polarizations to two corresponding baseband-frequency signals H1, V1 (with corresponding baseband carrier frequencies BBF₁, BBF₂ being, for example, between DC to several gigahertz, e.g., 3 GHz) and convey the baseband-frequency signals to a processor 156. The processor 156 may direct each of the two baseband signals H1, V1 to a respective analog-to-digital converter/digital-to-analog converter (ADC/DAC) 157, 158. The ADC/DACs 157, 158 may convert received baseband signals at the frequencies BBF₁, BBF₂ to digital signals for processing by a core of the processor 156 and may convert digital signals from the core of the processor 156 to analog signals at the respective baseband frequencies BBF₁, BBF₂ to be conveyed to the FEC 154. As another example, referring to FIG. 8, a system 160 includes a radiating element 162, an FEC 164, and a processor 166. The radiating element 162 may send and receive signals over multiple frequency bands, here in a single, horizontal, polarization, with the signals thus being horizontal-polarization signals H1 for a first frequency band and horizontal-polarization signals H2 for a second frequency band. The FEC 164 includes band-pass filters 168, 169 to pass the appropriate frequency of signals between the radiating element 162 and respective mixers of the FEC 164. While the filters 168, 169 are illustrated as being implemented between the radiating element 162 and the mixers, in other implementations the filters 168, 169 may be implemented between the mixers and the combiner. The FEC 164 here is configured to downconvert mm-wave signals to baseband signals of different frequencies and vice versa, conveying (transmitting or receiving) the baseband signals on a single transmission line, for example between the FEC 164 and the processor 166.

Still other configurations may be used. For example, referring to FIG. 9, a system 170 comprises a single radiating element 172 for multiple polarizations and multiple frequency bands, and may convert signals between mm-wave frequencies and intermediate frequencies or baseband frequencies. The radiating element 172 is configured to send and receive signals of multiple frequency bands (e.g., multiple mm-wave frequency bands) with respective polarizations (here, horizontal and vertical polarizations). As with the FEC 164 shown in FIG. 8, the FEC 174 includes filters, which may be implemented in the transmit/receive path as illustrated or in a different location within the transmit/receive path, for directing signals of respective frequency bands to respective mixers. The FEC 174 is configured to downconvert signals received from the radiating element 174 into lower-frequency (LF) signals and convey the LF signals on a single transmission line 176. The FEC 174 may also upconvert LF signals from the transmission line 176 to mm-wave signals and convey these signals to the radiating element 172. The LF signals may have intermediate frequencies, in which case the single transmission line 176 will be coupled to an IFC. Alternatively, the LF signals may have baseband frequencies, in which case the single transmission line 176 may be coupled to a processor. More than one transmission line may be used, e.g., in addition to the transmission line 176 as desired, e.g., if further frequency bands are used, or if separate circuitry for multiplexing/demultiplexing more LF signals is desired. The FEC 174 may be implemented using a single integrated circuit chip. In this case, a single PLL may be used to downconvert horizontally-polarized signals of different carrier frequencies to LF signals with frequencies LF₁ and LF₂, and a separate and different, single PLL may be used to downconvert vertically-polarized signals of different carrier frequencies to LF signals with frequencies LF₃ and LF₄, such that the signals are frequency multiplexed on the transmission line 176. The system 170 may thus have a reduced number of PLLs compared to implementing the FEC 174 using separate chips (e.g., one chip for one carrier frequency and another chip for another carrier frequency).

The disclosure is not limited to the various configurations shown. For example, components may be mixed and matched to form configurations other than those shown. For example, a single radiating element configured to send and receive multiple polarizations of signals may be used in configurations other than those shown in FIGS. 7 and 9. As another example, an FEC may be configured to downconvert to and upconvert from baseband frequencies in configurations other than those shown. Similarly, an FEC may be configured to downconvert to and upconvert from intermediate frequencies in configurations other than those shown. Further, configurations conveying other quantities of (e.g., more) signals than those shown may be used.

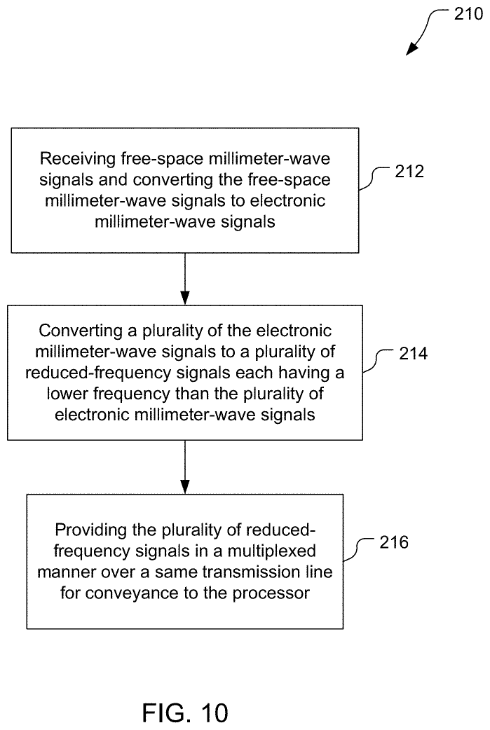

Referring to FIG. 10, with further reference to FIGS. 1-6, a method 210 of providing information from free-space millimeter-wave signals to a processor of a wireless communication device includes the stages shown. The method 210 is, however, an example only and not limiting.

At stage 212, the method 210 includes receiving free-space millimeter-wave signals and converting the free-space millimeter-wave signals to electronic millimeter-wave signals. For example, signals with different polarizations and the same carrier frequency may be received by the antenna unit 32. As another example, signals with different polarizations and with each of different carrier frequencies may be received by the antenna unit 32. As another example, signals with the same polarization but different carrier frequencies may be received by the antenna unit 32. The antenna unit 32, e.g., the radiating elements 51, 52, converts the received free-space signals into corresponding electronic signals, e.g., by transducing the received free-space signals. For example, as shown in FIGS. 4 and 6, differently-polarized free-space signals having a first carrier frequency and differently-polarized free-space signals having a second carrier frequency can be received and converted to corresponding electronic signals H1, V1, H2, V2.

At stage 214, the method 210 includes converting a plurality of the electronic millimeter-wave signals to a plurality of reduced-frequency signals each having a lower frequency than the plurality of electronic millimeter-wave signals. For example, the front-end circuitry 34 downconverts multiple electronic millimeter-wave signals to IF signals for indirect conveyance to the processor 38 via the IFC 36. Also or alternatively, the front-end circuitry 34 downconverts multiple electronic millimeter-wave signals to baseband signals for direct conveyance to the processor 38. The front-end circuitry 34 may produce the IF signals with different IF carrier frequencies and/or the baseband signals with different carrier frequencies for frequency-division multiplexed conveyance, or with the same or similar carrier frequencies for time-division multiplexed conveyance. The reduced-frequency signals may correspond to free-space millimeter-wave signals that have a same carrier frequency and different polarizations (see FIGS. 3, 4, and 7). As another example, the reduced-frequency signals may correspond to free-space millimeter-wave signals that have a same polarization and different carrier frequencies (see FIGS. 5, 6, and 8). As another example, the reduced-frequency signals may correspond to free-space millimeter-wave signals having different polarizations and different carrier frequencies (e.g., see FIG. 9).

At stage 216, the method 210 includes providing the plurality of reduced-frequency signals in a multiplexed manner over a same transmission line for conveyance to the processor. For example, different ones of the reduced-frequency signals may have different conveyance characteristics (e.g., frequency of signal, time of conveyance, etc.) such that the different ones of the reduced-frequency signals can be separately processed. In one embodiment, the front-end circuitry 34 provides reduced-frequency signals, as IF signals, to the processor 38 indirectly, e.g., to the IFC 36 that provides baseband signals to the processor 38. Also or alternatively, the front-end circuitry 34 provides reduced-frequency signals, as baseband signals, directly to the processor 38. For example, the front-end circuitry 34 may convey IF and/or baseband signals with different carrier frequencies concurrently over a single transmission line (e.g., coaxial cable) in a frequency division multiplexed (e.g., duplexed) manner, e.g., as shown in FIGS. 3-6. Providing multiple reduced-frequency signals over a single transmission line, e.g., to the IFC 70 or the processor 38, may reduce a quantity of transmission lines disposed between a processor and one or more antennas of a mobile wireless communication device compared to previous techniques. Where multiple signals of the same polarization and different carrier frequencies are received and converted to reduced-frequency signals, multiple reduced-frequency signals may be conveyed by the front-end circuitry 34 over each of multiple transmission lines in a multiplexed manner. For example, reduced-frequency signals corresponding to free-space signals of different polarizations and the same carrier frequency may be conveyed over the same transmission line, with signals corresponding to different free-space carrier frequencies conveyed on different transmission lines (e.g., see FIGS. 3, 4, and 7). As another example, reduced-frequency signals corresponding to free-space signals of the same polarization and different carrier frequencies may be conveyed over the same transmission line, with signals corresponding to a different polarization conveyed on a different transmission line (e.g., see FIGS. 5, 6, and 8). As another example, reduced-frequency signals corresponding to free-space millimeter-wave signals having different polarizations and different carrier frequencies may be conveyed over a single transmission line (e.g., see FIG. 9).

The method 210 may be modified, e.g., to include other stages. For example, the method 210 may include receiving the plurality of reduced-frequency signals from the transmission line, converting the plurality of reduced-frequency signals to first baseband signals, and providing the first baseband signals to the processor. For example, the IFC 70, or the IFC 118, or another IFC, may convert received IF signals to baseband signals of the same carrier frequency, or no carrier frequency, and provide the baseband signals to the processor 38.

The method 210 may include one or more further features. For example, the method 210 may include converting further electronic millimeter-wave signals (e.g., by the FEC 34), corresponding to further free-space millimeter-wave signals of a different carrier signal than the other free-space signals, to further reduced-frequency signals and providing the further reduced-frequency signals (e.g., by the FEC 34) in a multiplexed manner over a same transmission line to a processor (e.g., the processor 38). As another example, the method 210 may include receiving the reduced-frequency signals from the transmission line (e.g., by the IFC 36), converting the received signals (e.g., by the IFC 36) from IF signals to baseband signals, and providing the baseband signals (e.g., by the IFC 36) to a processor (e.g., the processor 38). As another example, the method 210 may further include bandpass filtering (e.g., by the filters 81, 82) the reduced-frequency signals before providing the reduced-frequency signals to a processor (e.g., the processor 38).

### OTHER CONSIDERATIONS

Also, as used herein, “or” as used in a list of items prefaced by “at least one of” or prefaced by “one or more of” indicates a disjunctive list such that, for example, a list of “at least one of A, B, or C,” or a list of “one or more of A, B, or C” means A or B or C or AB or AC or BC or ABC (i.e., A and B and C), or combinations with more than one feature (e.g., AA, AAB, ABBC, etc.).

As used herein, unless otherwise stated, a statement that a function or operation is “based on” an item or condition means that the function or operation is based on the stated item or condition and may be based on one or more items and/or conditions in addition to the stated item or condition.

Further, an indication that information is sent or transmitted or conveyed, or a statement of sending or transmitting or conveying information, “to” an entity does not require completion of the communication. Such indications or statements include situations where the information is conveyed from a sending entity but does not reach an intended recipient of the information. The intended recipient, even if not actually receiving the information, may still be referred to as a receiving entity, e.g., a receiving execution environment. Further, an entity that is configured to send or transmit or convey information “to” an intended recipient is not required to be configured to complete the delivery of the information to the intended recipient. For example, the entity may provide the information, with an indication of the intended recipient, to another entity that is capable of forwarding the information along with an indication of the intended recipient.

Substantial variations may be made in accordance with specific requirements. For example, customized hardware might also be used, and/or particular elements might be implemented in hardware, software (including portable software, such as applets, etc.) executed by a processor, or both. Further, connection to other computing devices such as network input/output devices may be employed.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, many of the operations can be performed in parallel or concurrently. In addition, the order of the operations may be rearranged. A process may have additional stages or functions not included in the figure. Furthermore, examples of the methods may be implemented by hardware, software, firmware, middleware, microcode, hardware description languages, or any combination thereof. When implemented in software, firmware, middleware, or microcode, the program code or code segments to perform the tasks may be stored in a non-transitory computer-readable medium such as a storage medium. Processors may perform the described tasks.

Components, functional or otherwise, shown in the figures and/or discussed herein as being connected or communicating with each other are communicatively coupled. That is, they may be directly or indirectly connected to enable communication between them.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of operations may be undertaken before, during, or after the above elements are considered. Accordingly, the above description does not bound the scope of the claims.

Further, more than one invention may be disclosed.

1. A wireless communication device comprising:
a housing configured to retain components of the wireless communication device;
an antenna unit configured to receive first free-space millimeter-wave signals and convert the first free-space millimeter-wave signals to first electronic millimeter-wave signals;
first circuitry disposed in the housing; and
front-end circuitry communicatively coupled to the antenna unit, the front-end circuitry coupled to the first circuitry by at least one transmission line;
wherein the front-end circuitry is configured to:
receive the first electronic millimeter-wave signals from the antenna unit;
convert the first electronic millimeter-wave signals to first reduced-frequency signals each having a lower frequency than the first electronic millimeter-wave signals; and
convey the first reduced-frequency signals over a same transmission line of the at least one transmission line in a multiplexed manner with different ones of the first reduced-frequency signals having different conveyance characteristics,
wherein the first circuitry is configured to receive, over the same transmission line, and process separately each of the different ones of the first reduced-frequency signals.

2. The wireless communication device of claim 1, wherein the different conveyance characteristics comprise frequency, and the front-end circuitry is configured to convey the first reduced-frequency signals concurrently over the same transmission line of the at least one transmission line in a frequency division multiplexed manner.

3. The wireless communication device of claim 1, wherein the first free-space millimeter-wave signals have a first carrier frequency, a first one of the first free-space millimeter-wave signals has a first polarization, and a second one of the first free-space millimeter-wave signals has a second polarization that is different from the first polarization.

4. The wireless communication device of claim 3, wherein:
the antenna unit is configured to receive second free-space millimeter-wave signals and convert the second free-space millimeter-wave signals to second electronic millimeter-wave signals, the second free-space millimeter-wave signals having a second carrier frequency different from the first carrier frequency, a first one of the second free-space millimeter-wave signals having the first polarization and a second one of the second free-space millimeter-wave signals having the second polarization; and
the front-end circuitry is configured to:
receive the second electronic millimeter-wave signals from the antenna unit;
convert the second electronic millimeter-wave signals to second reduced-frequency signals each having a lower frequency than the second electronic millimeter-wave signals;
convey the first reduced-frequency signals in a multiplexed manner over a first transmission line of the at least one transmission line; and
convey the second reduced-frequency signals in a multiplexed manner over a second transmission line of the at least one transmission line.

5. The wireless communication device of claim 4, wherein the first transmission line is the second transmission line.

6. The wireless communication device of claim 1, wherein:
a first one of the first free-space millimeter-wave signals has a first polarization and a first carrier frequency; and
a second one of the first free-space millimeter-wave signals has the first polarization and a second carrier frequency that is different from the first carrier frequency.

7. The wireless communication device of claim 6, wherein:
the at least one transmission line comprises a first transmission line and a second transmission line;
the antenna unit is configured to receive second free-space millimeter-wave signals and convert the second free-space millimeter-wave signals to second electronic millimeter-wave signals, a first one of the second free-space millimeter-wave signals has a second polarization, different from the first polarization, and the first carrier frequency, and a second one of the second free-space millimeter-wave signals has the second polarization and the second carrier frequency; and
the front-end circuitry is configured to:
receive the second electronic millimeter-wave signals from the antenna unit;
convert the second electronic millimeter-wave signals to second reduced-frequency signals each having a lower frequency than the second electronic millimeter-wave signals;
convey the first reduced-frequency signals in a multiplexed manner over the first transmission line; and
convey the second reduced-frequency signals in a multiplexed manner over the second transmission line.

8. The wireless communication device of claim 1, wherein the antenna unit is disposed proximate to at least one edge of the housing, the first circuitry is displaced from the antenna unit, and the front-end circuitry is disposed proximate to the antenna unit.

9. The wireless communication device of claim 8, further comprising a processor, wherein the first reduced-frequency signals are intermediate-frequency signals and the first circuitry comprises intermediate-frequency circuitry coupled to the at least one transmission line and to the processor, the intermediate-frequency circuitry being disposed proximate to the processor and configured to convert the first reduced-frequency signals to first baseband signals and to provide the first baseband signals to the processor.

10. The wireless communication device of claim 1, wherein the front-end circuitry includes a plurality of bandpass filters each configured and disposed to filter a respective one of the first reduced-frequency signals before the first reduced-frequency signals are conveyed over the same transmission line.

11. The wireless communication device of claim 1, wherein the front-end circuitry comprises a plurality of phase-locked loops configured to be used to convert the first electronic millimeter-wave signals to the first reduced-frequency signals, and configured to support carrier aggregation of signals received by the antenna unit.

12. The wireless communication device of claim 1, wherein the different conveyance characteristics comprise time of conveyance.

13. A wireless communication device comprising:
retaining means for retaining components of the wireless communication device;
processing means;
receiving means for receiving first free-space millimeter-wave signals at an antenna unit and converting the first free-space millimeter-wave signals to first electronic millimeter-wave signals; and
converting means, coupled to the receiving means, for converting the first electronic millimeter-wave signals to first reduced-frequency signals each having a lower frequency than the first electronic millimeter-wave signals, and for providing the first reduced-frequency signals in a multiplexed manner over a same first transmission line to the processing means with different ones of the first reduced-frequency signals having different conveyance characteristics such that the different ones of the first reduced-frequency signals can be separately processed.

14. The wireless communication device of claim 13, wherein the converting means are for providing the first reduced-frequency signals concurrently over the same transmission line in a frequency division multiplexed manner.

15. The wireless communication device of claim 13, wherein the first free-space millimeter-wave signals have a first carrier frequency, a first one of the first free-space millimeter-wave signals has a first polarization, and a second one of the first free-space millimeter-wave signals has a second polarization that is different from the first polarization.

16. The wireless communication device of claim 15, wherein:
the receiving means are further for receiving second free-space millimeter-wave signals at the antenna unit and converting the second free-space millimeter-wave signals to second electronic millimeter-wave signals, the second free-space millimeter-wave signals having a second carrier frequency different from the first carrier frequency, a first one of the second free-space millimeter-wave signals has the first polarization, and a second one of the second free-space millimeter-wave signals has the second polarization that is different from the first polarization; and
the converting means are further for converting the second electronic millimeter-wave signals to second reduced-frequency signals each having a lower frequency than the second electronic millimeter-wave signals, and for providing the second reduced-frequency signals in a multiplexed manner over a same second transmission line to the processing means.

17. The wireless communication device of claim 13, wherein:
a first one of the first free-space millimeter-wave signals has a first polarization and a first carrier frequency; and
a second one of the first free-space millimeter-wave signals has the first polarization and a second carrier frequency that is different from the first carrier frequency.

18. The wireless communication device of claim 17, wherein:
the receiving means are further for receiving second free-space millimeter-wave signals at the antenna unit and converting the second free-space millimeter-wave signals to second electronic millimeter-wave signals, a first one of the second free-space millimeter-wave signals has a second polarization and the first carrier frequency, and a second one of the second free-space millimeter-wave signals has the second polarization and the second carrier frequency, the second polarization being different from the first polarization; and
the converting means are further for converting the second electronic millimeter-wave signals to second reduced-frequency signals each having a lower frequency than the second electronic millimeter-wave signals, and for providing the second reduced-frequency signals in a multiplexed manner over a same second transmission line to the processing means.

19. The wireless communication device of claim 13, wherein the receiving means are disposed proximate to at least one edge of the retaining means, the processing means are displaced from the receiving means, and the converting means are disposed proximate to the receiving means, the wireless communication device further comprising baseband means, coupled to the first transmission line and to the processing means, disposed proximate to the processing means, for converting the first reduced-frequency signals to first baseband signals and providing the first baseband signals to the processing means.

20. A method of providing information from free-space millimeter-wave signals to a processor of a wireless communication device, the method comprising:
receiving free-space millimeter-wave signals at an antenna unit and converting the free-space millimeter-wave signals to a plurality of electronic millimeter-wave signals;
converting a plurality of the electronic millimeter-wave signals to a plurality of reduced-frequency signals each having a lower frequency than the plurality of electronic millimeter-wave signals; and
providing the plurality of reduced-frequency signals in a multiplexed manner over a same transmission line for conveyance to the processor with different ones of the plurality of reduced-frequency signals having different conveyance characteristics such that the different ones of the plurality of reduced-frequency signals can be separately processed.

21. The method of claim 20, wherein the plurality of reduced-frequency signals are provided concurrently over the same transmission line in a frequency division multiplexed manner.

22. The method of claim 20, wherein the plurality of reduced-frequency signals correspond to a plurality of the free-space millimeter-wave signals that have a same carrier frequency and different polarizations.

23. The method of claim 22, wherein the free-space millimeter-wave signals are a first plurality of free-space millimeter-wave signals, the plurality of electronic millimeter-wave signals is a first plurality of electronic millimeter-wave signals, the plurality of reduced-frequency signals are a first plurality of reduced-frequency signals, the carrier frequency is a first carrier frequency, the transmission line is a first transmission line, and the method further comprises:
converting a second plurality of the electronic millimeter-wave signals to a second plurality of reduced-frequency signals each having a lower frequency than the second plurality of the electronic millimeter-wave signals, the second plurality of reduced-frequency signals corresponding to a second plurality of free-space millimeter-wave signals that have a same second carrier frequency, different from the first carrier frequency, and different polarizations from each other; and
providing the second plurality of reduced-frequency signals in a multiplexed manner over a same second transmission line to the processor.

24. The method of claim 20, wherein the plurality of reduced-frequency signals correspond to a plurality of the free-space millimeter-wave signals that have a same polarization and different carrier frequencies.

25. The method of claim 24, wherein the free-space millimeter-wave signals are a first plurality of free-space millimeter-wave signals, the plurality of electronic millimeter-wave signals is a first plurality of electronic millimeter-wave signals, the plurality of reduced-frequency signals are a first plurality of reduced-frequency signals, the polarization is a first polarization, the transmission line is a first transmission line, and the method further comprises:
converting a second plurality of the electronic millimeter-wave signals to a second plurality of reduced-frequency signals each having a lower frequency than the second plurality of the electronic millimeter-wave signals, the second plurality of reduced-frequency signals corresponding to a second plurality of free-space millimeter-wave signals that have a same second polarization, different from the first polarization, and different carrier frequencies from each other; and
providing the second plurality of reduced-frequency signals in a multiplexed manner over a same second transmission line to the processor.

26. The method of claim 20, further comprising:
receiving the plurality of reduced-frequency signals from the transmission line;
converting the plurality of reduced-frequency signals from intermediate-frequency signals to first baseband signals; and
providing the first baseband signals to the processor.

27. The method of claim 20, further comprising bandpass filtering the plurality of reduced-frequency signals before providing the plurality of reduced-frequency signals to the processor.

28. A wireless communication device comprising:
an antenna unit configured to receive multiple free-space composite signals having different inbound millimeter-wave carrier frequencies and each comprising multiple free-space component signals of different polarizations, the antenna unit configured to convert the multiple free-space component signals into electronic component signals;
radio-frequency circuitry, coupled to the antenna unit, configured to convert the electronic component signals to intermediate signals each having a lower frequency than the inbound millimeter-wave carrier frequencies and to convey the intermediate signals over multiple coaxial lines such that each coaxial line concurrently conveys multiple intermediate signals of different intermediate carrier frequencies; and
intermediate-frequency circuitry, coupled to the radio-frequency circuitry, configured to convert each of the intermediate signals to a respective baseband signal and to provide each respective baseband signal to a processor of the wireless communication device.

29. The device of claim 28, wherein the radio-frequency circuitry is configured to convey the multiple intermediate signals over the multiple coaxial lines such that a plurality of the intermediate signals corresponding to respective ones of the multiple free-space component signals of different polarizations and a shared one of the inbound millimeter-wave carrier frequencies will be conveyed on a shared coaxial line concurrently.

30. The device of claim 28, wherein the radio-frequency circuitry is configured to convey the multiple intermediate signals over the multiple coaxial lines such that a plurality of the intermediate signals corresponding to respective ones of the multiple free-space component signals of different ones of the inbound millimeter-wave carrier frequencies and similar polarizations will be conveyed on a shared coaxial line concurrently.

31. The wireless communication device of claim 1, wherein the first circuitry comprises a processor.
